(19) United States
(12) Patent Application Publication
(10) Pub. No.: US 2004/0087097 A1
(43) Pub. Date: May 6, 2004

(54) Method of ultra thin base fabrication for Si/SiGe hetro bipolar transister

(75) Inventors: Li-Shyue Lai, Hsinchu (TW); Pang-Shiu Chen, Hsinchu (TW); Shin-Chii Lu, Hsinchu (TW); Chee-Wee Liu, Taipei (TW)

Correspondence Address: BACON & THOMAS, PLLC, 625 SLATERS LANE, FOURTH FLOOR, ALEXANDRIA, VA, 22314

(73) Assignee: Industrial Technology Research Institute, Hsinhchu (TW)

(21) Appl. No.: 10/423,939

(22) Filed: Apr. 28, 2003

(30) Foreign Application Priority Data
Nov. 5, 2002 (TW) 091132630

(51) Int. Cl. H01L 21/331

(52) U.S. Cl. 438/376

(57) ABSTRACT

A manufacture method of a semiconductor device, and more particularly to the manufacture method of a silicon/silicon-germanium heterogeneous bipolar transistor (HBT) device with ultra-thin base, which mainly utilized the method of doping carbon atoms in the silicon-germanium (SiGe) spacer layer in order to suppress the out-diffusion of boron, increase the amount of doped boron in base, germanium (Ge) concentration, and critical thickness, and decrease the thickness of silicon-germanium spacer layer, and achieve the objective of raising the device's high frequency property.

### BACKGROUND OF THE INVENTION

(1) Field of the Invention

The present invention relates to the manufacture method of a semiconductor device, and more particularly to the manufacture method of a silicon/silicon-germanium heterogeneous bipolar transistor (HBT) device with ultra-thin base.

(2) Description of the Prior Art

Currently the silicon/silicon-germanium heterogeneous bipolar transistor (HBT) process is a new technology. The emitter, base, and collector are vertically lined and the electron current in the tunnel flows vertically, which, through its structure advantages, results a rather high power density, Therefore, with same output power, the chip size of the silicon/silicon-germanium heterogeneous bipolar transistor (HBT) may be smaller and it can be operated with single voltage source.

Since the silicon/silicon-germanium heterogeneous bipolar transistor (HBT) is with the characteristics of better linear effect and good power efficiency, it can be used as crucial device technology of mobile phones efficiency, it can be used as crucial device technology of mobile phones and personal communication services.

Traditionally, the method to increase the high frequency property of a silicon/silicon-germanium heterogeneous bipolar transistor (HBT) device mainly depends on changing the characteristics of boron and germanium in the silicon-germanium base layer. (The IHP company in Germany has published a paper in which, by adding boron into the base transition layer, the maximum current cutting frequency ft increased 1.35 times and the maximum power cutting frequency fmax increased 1.6 times.) The crucial technology utilizes the property of germanium (Ge) in the grade layer to establish an accelerative electric field in the base area and achieve the high-speed conduction property. The sequential hot treatment and implant processes generate the temperate transient enhanced diffusion (TED) effect that causes the serious out-diffusion of boron in base to increase the effective base width (W_{B}) and generate a parasitic barrier on the conduction band to reduce the device's high frequency property.

Therefore some people add an undoped spacer layer between the base and the collector to improve the condition of boron diffusion. However the increased thickness may influence the carriers' transmission speed, so in the patent (U.S. Pat. No. US2002/0020851) of Japanese Fujitsu company its main characteristics is that the entire base is doped with carbon atoms as shown in FIG. 1. But this method may cause the neutral base recombination current to decrease current effectiveness and the defects density of intervals to influence the device properties (such as increasing device's interference signals).

In order to solve the device's high frequency property influenced by the boron diffusion, the present invention proposes a manufacture method of a silicon/silicon-germanium heterogeneous bipolar transistor (HBT) device with ultra-thin base to achieve the objective of suppressing the boron diffusion.

### SUMMARY OF THE INVENTION

The present invention relates to the manufacture method of a silicon/silicon-germanium heterogeneous bipolar transistor (HBT) device with ultra-thin base, wherein the spacer layer of the base is carbon-doped to effectively suppress the boron diffusion and achieve the objective of increasing the device's high frequency property.

In order to achieve the above objective, the manufacture method of a silicon/silicon-germanium heterogeneous bipolar transistor (HBT) device with ultra-thin base of the present invention utilizes the base structure of a transistor device which comprises a spacer layer, a grade layer, and a cap layer, wherein the spacer layer is doped with carbon atoms to effectively raises the device's high frequency property.

### BRIEF DESCRIPTION OF THE DRAWINGS

The present invention will now be specified with reference to its preferred embodiment illustrated in the drawings, in which

FIG. 1 is a schematic view of the carbon-doped concentration of a prior HBT device.

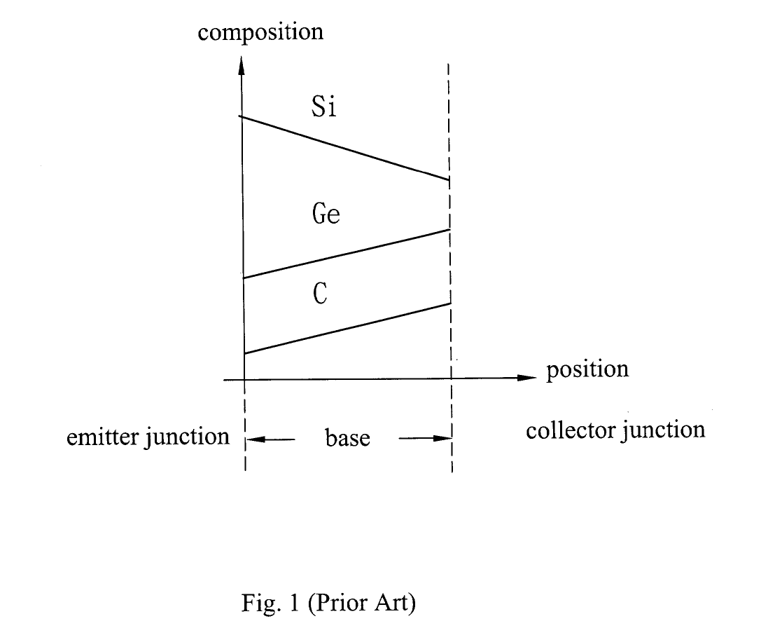

FIG. 2 is a schematic view of the base structure of a silicon-germanium HBT device.

FIG. 3 is a schematic view of the carbon-doped concentration of a preferred embodiment.

FIG. 4 is a schematic view of the carbon-doped concentration of another preferred embodiment.

FIG. 5 is a comparison graph of the characteristic curves among the collector currents (Ic) of the base without dope-carbon, the entire base doped with carbon, and only the spacer with doped-carbon.

### DESCRIPTION OF THE PREFERRED EMBODIMENT

The invention disclosed herein is directed to the manufacture method of a silicon/silicon-germanium heterogeneous bipolar transistor (HBT) device with ultra-thin base. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

The important part of the present invention is that by adding a proper amount of carbon atoms in the undoped spacer layer to suppress the boron out-diffusion, it increases the concentration of doped boron in the base, critical thickness, and reduce the thickness of silicon-germanium (SiGe) spacer layer to achieve the objective of raising the device's high frequency property.

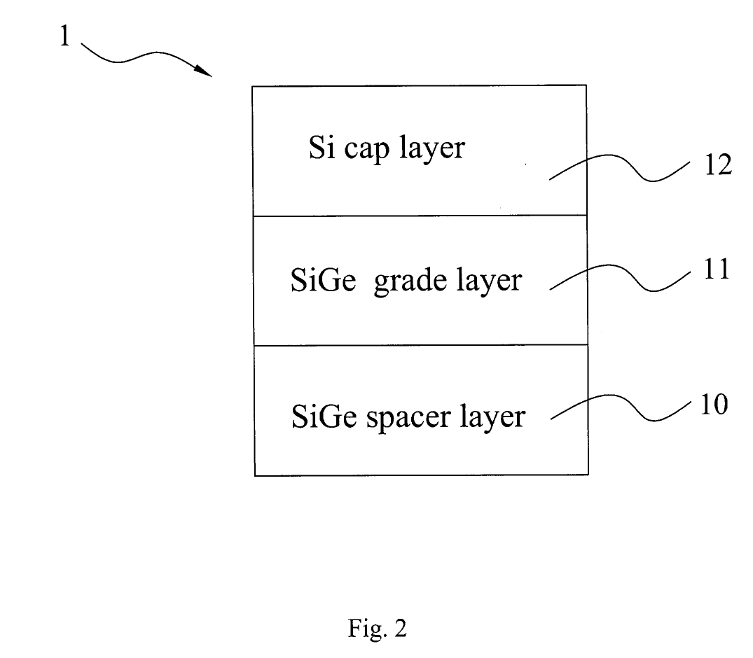

First, please refer to FIG. 2, the structural schematic view of the base 1 of a silicon-germanium heterogeneous bipolar transistor (HBT) device, a preferred embodiment in accordance with the present invention. It is a three-layer structure, wherein the first layer is an undoped SiGe spacer layer 10, the second layer is the boron-doped SiGe grade layer 11, and the third layer is an undoped Si cap layer 12. Since the manufacture process is the prior art and not the focus of the present invention, it will not be described in detail here.

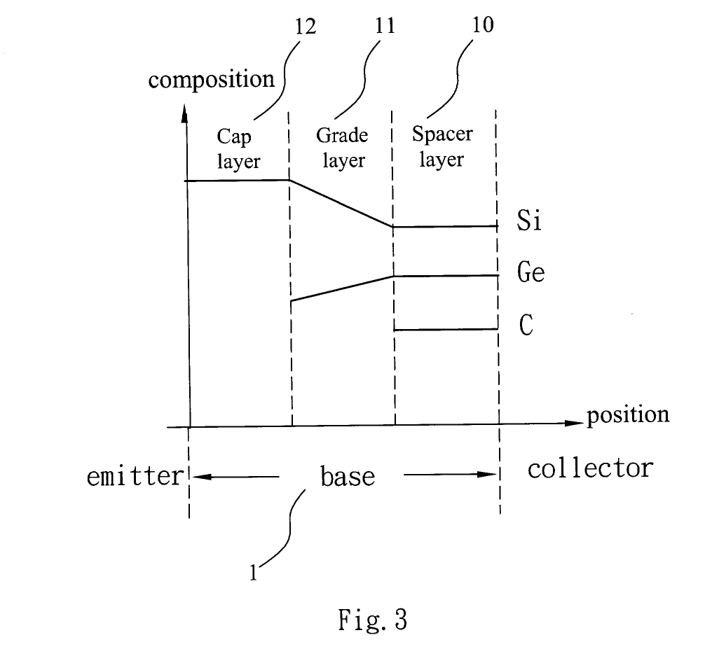

Please refer to FIG. 3, the doped concentration schematic view of a preferred embodiment in accordance with the present invention, wherein it utilizes in-situ process to dope carbon atoms in the SiGe spacer 10 of a base which is generated by the use of ultra-high vacuum CVD, and the concentration of the doped-carbon is less than 1%. Therefore the composition in the spacer layer 10 comprises SiGe and doped-carbon atoms, while the grade layer 11 comprises doped-boron SiGe and the cap layer 12 comprises undoped silicon.

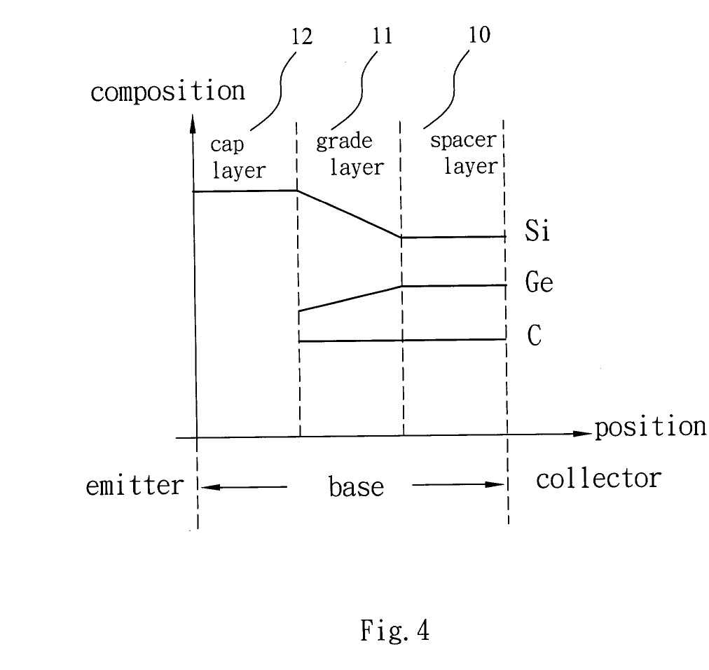

Please refer to FIG. 4, the doped concentration schematic view of another preferred embodiment in accordance with the present invention, wherein, different from the previous embodiment, it dopes carbon atoms into the second SiGe grade layer 11 and the first SiGe spacer layer 10 and the doped concentration is less than 1%. Therefore the composition of spacer layer 10 comprises silicon-germanium (SiGe) and doped-carbon, while the grade layer 11 comprises silicon-germanium (SiGe) layer with doped-boron and doped-carbon, and the cap layer 12 comprises undoped silicon.

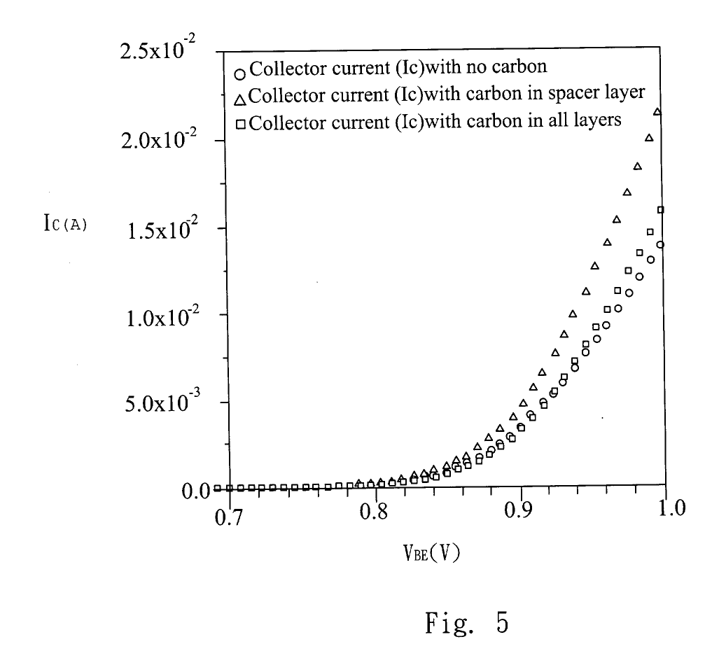

Please refer to FIG. 5, a comparison graph of the characteristic curves among the collector currents (Ic) of the base without dope-carbon, the entire base doped with carbon, and only the spacer with doped-carbon. Because the collector current (Ic) of the device is direct proportional to the square of carrier concentration (nᵢ²), as shown in the graph, the device with doped-carbon in the spacer layer can effectively suppress the boron diffuse into the collector area to increase collector current (about 140%), while the device with doped-carbon in entire area reduces collector current due to too many trap centers that generate neutral base recombination current.

The above are the descriptions of the manufacture method of a silicon/silicon-germanium heterogeneous bipolar transistor (HBT) device with ultra-thin base. Of the present invention, wherein the spacer layer of the base is carbon-doped; or the grade layer and the spacer layer us carbon-doped and the concentration of carbon atoms is less than 1% to improve the condition of boron diffusion. The present invention had the following advantages, compared to the prior art which is carbon-doped the entire base area:

(1) It is able to reduce the interstitial of the carbon atoms to reduce the recombination centers, increase carrier lifetime, reduce neutral base recombination current, and, because of the reduction of trap center, the device's low frequency 1/f interference signals are also reduced.

(2) This invention reduces the effects of raising the emitter/base (E/B) critical plane potential barrier by adding carbon atoms in the emitter/base (E/B) critical plane to lower the band gap.

(3) This invention reduces the accelerative diffusion of arsenic (As) into the base caused by the doped-carbon in the cover layer, so that emitter/base (E/B) critical plane is in the area with lower drift current field and not influence the device's property.

(4) This invention reduces the thickness of silicon-germanium (SiGe) spacer layer and increases the amount of doped-boron in the silicon-germanium grade layer, and allows the device to be produced in a looser temperature condition and raise the device's high frequency property.

(5) According to some experimental results, by doping carbon in the spacer layer and not the entire area, the direct current property of the device increases about 140% and the high frequency property raises 8 to 16%.

(6) Concluded from the above, the more serious boron diffusion, the smaller collector current (Ic) becomes. Therefore the device with doped-boron in spacer layer to effectively suppress the out-diffusion of boron into the collector area and further increase the collector current by about 140% and the device's current property. On the contrary, the collector current of the device with doped-carbon in the entire area, because of too much trap centers that generate neutral base recombination current, is reduced.

While the present invention has been particularly shown and described with reference to a preferred embodiment, it will be understood by those skilled in the art that various changes in form and detail may be without departing from the spirit and scope of the present invention.

What is claimed is:

1. A manufacture method of a silicon/silicon-germanium heterogeneous bipolar transistor (HBT) device with ultra-thin base applies on the base structure of said heterogeneous bipolar transistor (HBT) device, and said base structure comprises of a spacer layer, a grade layer, and a cap layer, wherein the characteristics include:
said spacer layer is doped with a proper amount of carbon atoms in order to suppress the out-diffusion of boron atoms.

2. The manufacture method of a silicon/silicon-germanium heterogeneous bipolar transistor (HBT) device with ultra-thin base according to claim 1, wherein said grade layer is doped with less than 1% of carbon atoms.

3. The manufacture method of a silicon/silicon-germanium heterogeneous bipolar transistor (HBT) device with ultra-thin base according to claim 1, wherein the concentration of said carbon is less than 1%.

4. The manufacture method of a silicon/silicon-germanium heterogeneous bipolar transistor (HBT) device with ultra-thin base according to claim 1, wherein the material of said spacer layer is undoped silicon-germanium (SiGe) layer, the material of said grade layer is boron-doped silicon-germanium (SiGe) layer, and the material of said cap layer is undoped silicon layer.

5. The manufacture method of a silicon/silicon-germanium heterogeneous bipolar transistor (HBT) device with ultra-thin base according to claim 1, wherein said spacer layer is doped with carbon atoms by the in-situ doped process.

6. The manufacture method of a silicon/silicon-germanium heterogeneous bipolar transistor (HBT) device with ultra-thin base according to claim 2, wherein said grade layer is doped with carbon atoms by the in-situ doped process.

7. A manufacture method of a silicon/silicon-germanium heterogeneous bipolar transistor (HBT) device with ultra-thin base applies on the base structure of said heterogeneous bipolar transistor (HBT) device, and said base structure comprises of a spacer layer, a grade layer, and a cap layer, wherein the characteristics include:
said spacer layer and said grade layer are doped with a proper amount of carbon atoms in order to suppress the out-diffusion of boron atoms.

8. The manufacture method of a silicon/silicon-germanium heterogeneous bipolar transistor (HBT) device with ultra-thin base according to claim 7, wherein the concentration of said carbon is less than 1%.

9. The manufacture method of a silicon/silicon-germanium heterogeneous bipolar transistor (HBT) device with ultra-thin base according to claim 7, wherein the material of said spacer layer is undoped silicon-germanium (SiGe) layer, the material of said grade layer is boron-doped silicon-germanium (SiGe) layer, and the material of said cap layer is undoped silicon layer.

10. The manufacture method of a silicon/silicon-germanium heterogeneous bipolar transistor (HBT) device with ultra-thin base according to claim 7, wherein said spacer layer and said grade layer are doped with carbon atoms by the in-situ doped process.

11. A manufacture method of a silicon/silicon-germanium heterogeneous bipolar transistor (HBT) device with ultra-thin base applies on the base structure of said heterogeneous bipolar transistor (HBT) device, and said base structure comprises of a spacer layer, a grade layer, and a cap layer, wherein the characteristics include:
said spacer layer and said grade layer are doped with less than 1% of carbon atoms in order to suppress the out-diffusion of boron atoms.

12. The manufacture method of a silicon/silicon-germanium heterogeneous bipolar transistor (HBT) device with ultra-thin base according to claim 11, wherein the material of said spacer layer is undoped silicon-germanium (SiGe) layer, the material of said grade layer is boron-doped silicon-germanium (SiGe) layer, and the material of said cap layer is undoped silicon layer.

13. The manufacture method of a silicon/silicon-germanium heterogeneous bipolar transistor (HBT) device with ultra-thin base according to claim 11, wherein said spacer layer and said grade layer are doped with carbon atoms by the in-situ doped process.
